(19) United States
(12) Patent Application Publication
(10) Pub. No.: US 2006/0063308 A1
(43) Pub. Date: Mar. 23, 2006

(54) Method for cleaning semiconductor device having dual damascene structure

(75) Inventor: Joon Bum Shim, Seongnam-si (KR)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(73) Assignee: DongbuAnam Semiconductor Inc.

(21) Appl. No.: 11/231,441

(22) Filed: Sep. 19, 2005

(30) Foreign Application Priority Data
Sep. 17, 2004 (KR) 10-2004-0074600

(51) Int. Cl. H01L 21/44

(52) U.S. Cl. 438/115

(57) ABSTRACT

A method to clean a dual damascene structure includes forming a photoresist pattern on an interlayer dielectric; forming a dual damascene structure by etching the interlayer dielectric using the photoresist pattern as an etch mask; removing the photoresist pattern by an ashing process; and cleaning the dual damascene structure with a cleaning solution mixture that includes a first solution for removing polymer (that may be formed during the etching of the interlayer dielectric) and photoresist residue, and a second solution for removing native oxide (that may be formed on the bottom of the dual damascene structure). The first solution may include an organic solution further including hydroxylamine, and the second solution includes an HF solution or buffered HF solution. The cleaning step may also use an additive that has metal corrosion resistance.

This application claims the benefit of Korean Patent Application No. 10-2004-0074600, filed on Sep. 17, 2004, which is hereby incorporated by reference in its entirety.

### BACKGROUND OF THE INVENTION

1. Field of the Invention

The present invention relates to semiconductor technologies, and more particularly to a method for cleaning semiconductor devices that have dual damascene structure.

2. Description of the Related Art

As integration of semiconductor IC devices increases, the metal lines formed within the IC devices are generally made narrower and multilayered. The decrease of the width of metal line can produce signal delay due to the increase of electrical resistance and capacitance of the metal lines. For reducing the signal delay, copper metal having low resistance has been widely used for the metal line.

The copper has an electric resistance that is about 62% of the resistance of aluminum, and superior resistance against electromigration, which improves the reliability of copper metallization in highly integrated and high speed devices. Because the copper is not dry-etched (a processing difference from aluminum), a damascene process that forms a trench in semiconductor substrate, deposits metal film, and polishes the metal film by a CMP (Chemical Mechanical Polishing) has been developed.

The damascene process has evolved to form a dual damascene structure in which only a single metal deposition step is used to simultaneously form the metal lines and metal in the vias. That is, both trenches and vias are formed in a dielectric layer. The trenches and vias are defined using two separate lithography steps. When comparing to a single damascene process, one metal deposition step and one CMP step are eliminated in the dual damascene process. The reduction in the number of processing steps is another of the benefits that have driven the development of dual damascene processes.

FIGS. 1A to 1F are cross sectional views for illustrating the conventional method for forming a dual damascene structure.

According to the conventional method, a first interlayer dielectric 12 is deposited on a semiconductor substrate 10, and an etch stop layer 14 and a second interlayer dielectric 16 are sequentially deposited as shown in FIG. 1A. The substrate 10 may have gate electrodes or metal lines formed thereon.

Referring to FIG. 1B, a first photoresist pattern 18 that defines vias is formed through a photolithographic process.

Referring to FIG. 1C, a portion of the second interlayer dielectric 16 that is exposed through the first photoresist pattern 18 is dry etched. In FIG. 1C, the dry etched portion of the second interlayer dielectric is denoted by reference numeral ‘1 6a’. During the etching process, the etch stop layer 14 prevents the further etching of the second interlayer dielectric 16. Then, the first photoresist pattern 18 is removed.

Referring to FIG. 1D, a second photoresist pattern 22 for defining trenches is formed through the photolithographic process.

Subsequently, as shown in FIG. 1E, trenches 24 for metal lines are formed by etching a portion of the dry etched second interlayer dielectric 16a, which is exposed through the second photoresist pattern 22, and at the same time, via holes 20 are formed by dry etching the etch stop layer 14 and the first interlayer dielectric 12. The etched etch stop layer 14 and the first interlayer dielectric 12 are represented in FIG. 1E by ‘14a’ and ‘12a’, respectively.

Here, the via hole 20 of the conventional dual damascene structure tends to have a native oxide film 26 on the bottom surface of the via, and polymer 28 may be formed on sidewalls of via hole 20 and the inner surfaces of trench 24 as shown in FIG. 1E.

Referring to FIG. 1F, the second photoresist pattern 22 is removed, the via hole 20 is filled with copper metal in the same deposition step that fills the trench 24. After filling, the excess copper metal that is deposited outside the trench is removed by a chemical mechanical polishing (CMP) process, and a planar structure with metal lines is achieved.

In the conventional method, a wet etching process is employed for removing the residual photoresist 22a that remains after the removal of the second photoresist pattern 18. The wet etching process typically uses SPM solution (generally, a mixture of aqueous H₂SO₄ and H₂O₂) for gate contacts, and N396 solution (hydroxylamine mixed solution) or SMC solution (NH₄OH+CH₃COOH+D.I. water) for a dual damascene structure, to prevent the corrosion of copper metal and remove the polymer 28 formed on the dielectric.

However, the conventional cleaning process which uses the SPM solution generally requires a temperature higher than 140° C., which results in a dangerous environment to the operators and can cause premature erosion of equipment, environmental pollution, and waste water treatment. Moreover, the conventional process employing the N396 or SMC solution strives to remove polymer while preventing copper corrosion, which produces conflicting results. Therefore, an optimal recipe may be difficult to choose.

Further, the residual photoresist 22a may cause a rugged or rough surface topology, short circuits and/or a high resistance of the dual damascene metal structure, which results in a defocus phenomenon in the subsequent photolithographic processes and failure of accurate patterning. Moreover, the native oxide 26 that forms in the via hole 20 may lead to high resistance of the dual damascene metal structure and can degrade the operational performance of the structure.

### SUMMARY OF THE INVENTION

It is, therefore, an object of the present invention to provide an improved cleaning process suitable for use in cleaning a dual damascene trench and via structure.

According to one embodiment of the present invention, a method for cleaning semiconductor devices comprises the steps of: forming a photoresist pattern on an interlayer dielectric; forming a dual damascene structure by etching the interlayer dielectric using the photoresist pattern as an etch mask; removing the photoresist pattern by an ashing process; cleaning the dual damascene structure with a cleaning solution mixture that includes a first solution for removing polymer that may be formed on inner surfaces of the dual damascene structure during the etching of the interlayer dielectric and residue of the photoresist pattern (e.g., on the interlayer dielectric), and a second solution for removing native oxide that may be formed on the bottom of the dual damascene structure. The first solution may comprise an organic solution including a hydroxylamine, and the second solution comprises an HF solution or buffered HF (e.g., aqueous HF and NH₄F mixture) solution. The cleaning step may further use or include an additive that has metal corrosion resistance, such as phosphoric acid, acetic acid and methanol.

These and other aspects will become evident by reference to the description of the invention.

### BRIEF DESCRIPTION OF DRAWINGS

FIGS. 1A to 1F are cross sectional views for illustrating process steps for forming conventional dual damascene structures.

FIG. 2 is a cross sectional view for illustrating the dual damascene (e.g., trench and via) structure to which a cleaning process of the present invention has been applied.

### DETAILED DESCRIPTION OF THE PREFERRED EMBODIMENTS

With reference to the accompanying drawings, the preferred embodiments of the present invention will be explained.

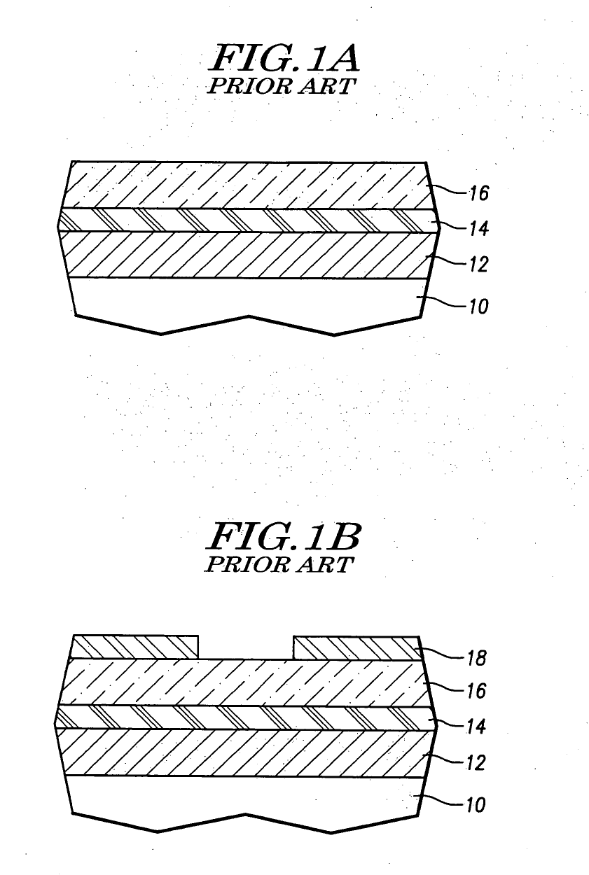

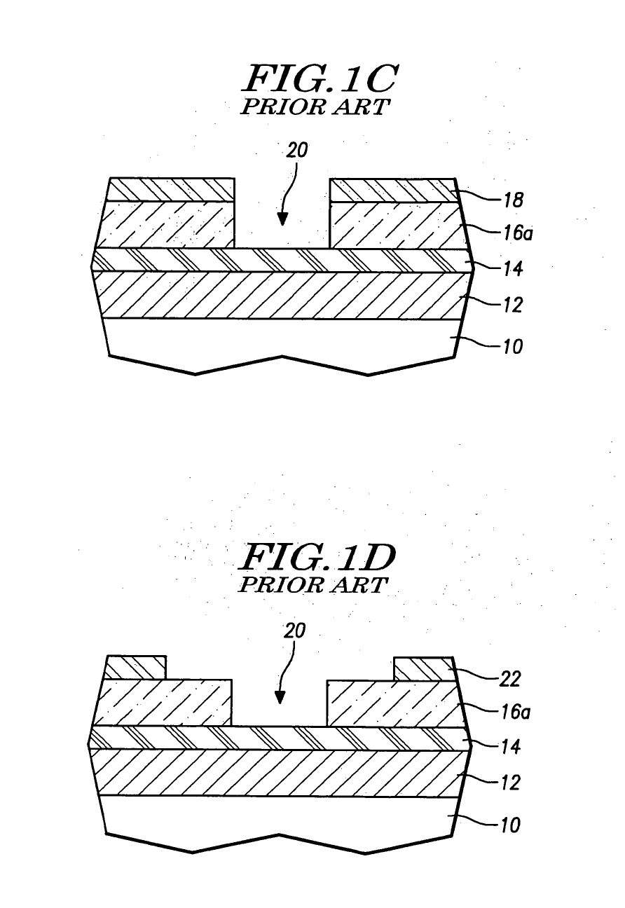

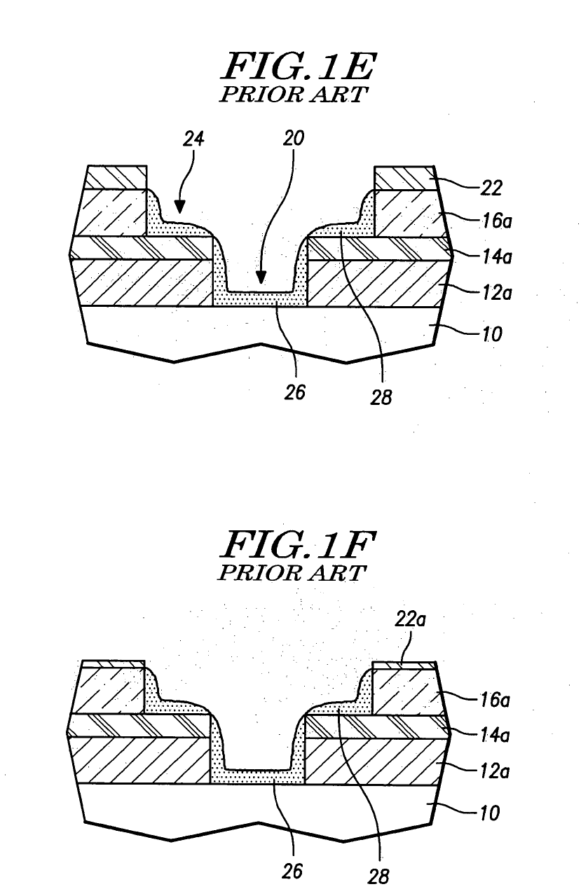

A method for cleaning dual damascene structures in an interlayer dielectric that may include, for example (and optionally in sequence), a lower barrier (insulator) layer, a lower dielectric layer, an etch stop layer, and an upper dielectric layer according to one aspect of the present invention is applicable to the structure explained above with reference to FIGS. 1A to 1F. However, it should be noted that the present invention can be also applied to any dual damascene trench-and-via structures in a dielectric layer that may be produced by trench-first dual damascene sequences, via-first dual damascene sequences, or self-aligned (or buried-via) dual damascene sequences.

For the purpose of description, one embodiment of the present invention is explained with reference to the structure shown in FIG. 1A to 1F. The conventional dual damascene structure as shown in FIG. 1F is obtained by removing the first and second dielectric layers 12a and 16a by dry etching and the second photoresist pattern 22 by wet etching. In contrast, the photoresist pattern 22 employed as a mask in the dry etching process of the present invention may be removed by a dry ashing process, rather than the conventional wet etching process (although the present invention is also applicable to processes that remove the photoresist pattern 22 by wet etching or wet stripping).

The present invention provides an improved technology that enables removal, essentially at one time, the residual photoresist 22a on the dielectric layer 16a, polymer 28 that may be formed on sidewalls of the via hole and the inner surfaces of the trench, and any native or natural oxide 26 formed, for example, on the bottom surface of the via holes.

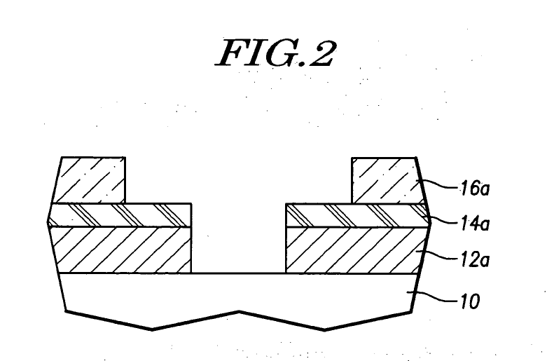

FIG. 2 is a cross sectional view of a dual damascene structure formed (and/or processed) by a preferred embodiment of the present invention. The structure of FIG. 2 may be obtained after performing a cleaning process in which a mixture of solutions adapted to remove the residual photoresist 22a and the polymer 28, (optionally) have metallic corrosion resistance, and remove the native oxide 26 are employed. As shown in FIG. 2, the residual photoresist 22a, native oxide 26 and polymer 28 are substantially entirely removed from the dual damascene (e.g., trench and via) structure.

The cleaning solution mixture of the present invention may include an organic solution (or aqueous solution) including hydroxylamine for removing the residual photoresist 22a and polymer 28. As is known in the art, hydroxylamine is readily soluble in a wide variety of organic solvents (e.g., methanol, ethanol, n-propanol, isopropanol, diethyl ether, tetrahydrofuran, dioxane, methylene chloride, chloroform, etc.) and soluble in water over a large percentage range, either by volume or weight percent. In addition, organic hydroxylamines (e.g., compounds of the formula (RₓH₂₋ₓN—OH, where x is 1 or 2 and R is an organic group such as alkyl, aryl, or alkyl or aryl substituted with a wide variety of conventional substituents known to those of skill in the art, or when x=2, the two R groups together can form a ring with the N atom of the hydroxylamine moiety). The cleaning solution mixture of the present invention may further include an HF or buffered HF (e.g., an aqueous mixture of NH₄F and HF, commonly referred to as “buffered oxide etch[ant],” or BOE) solution for removing the native oxide 26. In general, an organic solution including a hydroxylamine comprises the base of cleaning solution (e.g., it is present in an amount of greater than 50, 60, 75 vol. % or more), and the native oxide etching solution is used as an additive.

The via hole cleaning process using the solution mixture may be performed at temperature ranging from 25° C. to 35° C. Alternatively, the present cleaning process may be performed at a higher temperature (e.g., from 35° C. to 50° C.), or may be performed at an ambient temperature.

The HF solution or buffered HF solution for removing the native oxide 26 may be used in an amount of from 0.1 wt % to 50 wt %, or an amount of from 0.01 vol % to 5 vol %, in the cleaning solution mixture.

When a fluorine-based solution is included in the cleaning solution, the polymer and native oxide can be easily removed, but metal corrosion may occur. For preventing metal corrosion, the present invention advantageously employs an additive having metal corrosion resistance. In a preferred embodiment, the additive may comprise a solution adapted to prevent, inhibit or reduce corrosion of the metal subsequently deposited into the via and trench (which metal may comprise copper, tantalum and/or titanium). The solution may include phosphoric acid, acetic acid and/or methanol (preferably all three in a conventional volume or weight ratio), and may be present in a range of from 5 vol % to 10 vol % in the cleaning solution mixture.

As explained above, the present invention may further include an ashing process for removing the photoresist pattern. The ashing process may comprise exposing the photoresist pattern (or the residual photoresist) to a dry oxygen plasma. The ashing process is generally carried out before the cleaning process, according to the present invention.

When the dry etched photoresist pattern is removed without the ashing process, the surface of the photoresist pattern may be hardened, and thus the photoresist pattern removal may become unsatisfactory. By adding the ashing process, the cleaning effect can be enhanced.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A method for cleaning semiconductor devices, comprising the steps of:
forming a photoresist pattern on an interlayer dielectric;
forming a dual damascene structure by etching the interlayer dielectric using the photoresist pattern as an etch mask;
removing the photoresist pattern by an ashing process; and
cleaning the dual damascene structure with a cleaning solution mixture that includes a first solution for removing polymer formed on inner surfaces of the dual damascene structure during the etching step and residue of the photoresist pattern on the interlayer dielectric, and a second solution for removing native oxide formed on the bottom of the dual damascene structure.

2. The method of claim 1, wherein the first solution comprises an organic solution including a hydroxylamine.

3. The method of claim 1, wherein the second solution comprises an HF solution or a buffered HF solution.

4. The method of claim 1, wherein the cleaning solution mixture further comprises an additive having metal corrosion resistance.

5. The method of claim 4, wherein the additive includes phosphoric acid, acetic acid and methanol.

6. The method of claim 4, wherein the additive is included in the cleaning solution mixture in an amount of from 5 vol % to 10 vol %.

7. The method of claim 1, wherein the ashing process comprises exposing the photoresist pattern to an oxygen plasma.

8. The method of claim 1, wherein the cleaning step is performed at temperature ranging from 25° C. to 35° C.

9. The method of claim 1, wherein the second solution is included in the cleaning solution mixture in an amount of from 0.01 vol % to 5 vol %.

10. A method for cleaning a semiconductor device, comprising the steps of:
removing a photoresist pattern on an interlayer dielectric in the semiconductor device having a dual damascene structure; and
cleaning the dual damascene structure with a cleaning solution mixture that includes a first solution adapted to remove polymers and/or photoresist residue, and a second solution adapted to remove native oxide in the dual damascene structure.

11. The method of claim 10, further comprising, before the step of removing the photoresist pattern, etching the interlayer dielectric using the photoresist pattern as an etch mask to form the dual damascene structure.

12. The method of claim 10, wherein the first solution comprises a hydroxylamine.

13. The method of claim 10, wherein the second solution comprises an HF solution or a buffered HF solution.

14. The method of claim 10, wherein the cleaning solution mixture further comprises a corrosion resistance additive.

15. The method of claim 14, wherein the additive includes one or more of phosphoric acid, acetic acid and methanol.

16. The method of claim 14, wherein the additive is present in the cleaning solution mixture in an amount of from 5 vol % to 10 vol %.

17. The method of claim 10, wherein the step of removing the photoresist pattern comprises an ashing process.

18. The method of claim 17, wherein the ashing process comprises exposing the photoresist pattern to an oxygen plasma.

19. The method of claim 10, wherein the cleaning step is performed at temperature of from 25° C. to 35° C.

20. The method of claim 10, wherein the second solution is included in the cleaning solution mixture in an amount of from 0.01 vol % to 5 vol %.
